(19) United States
(12) Patent Application Publication
(10) Pub. No.: US 2007/0108504 A1
(43) Pub. Date: May 17, 2007

(54) NON-VOLATILE MEMORY AND MANUFACTURING METHOD AND OPERATING METHOD THEREOF

(76) Inventors: Yung-Chung Lee, Taipei County (TW); Hann-Ping Hwang, Hsinchu City (TW); Chin-Chung Wang, Hsinchu (TW); Chih-Ming Chao, Hsinchu City (TW); Saysamone Pittikoun, Hsinchu County (TW); Chih-Chen Cho, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,507

(22) Filed: Mar. 31, 2006

(30) Foreign Application Priority Data
Nov. 11, 2005 (TW) 94139580

(51) Int. Cl. H01L 29/788; H01L 29/76; H01L 21/336

(52) U.S. Cl. 257/316; 438/257; 438/258; 438/264; 257/319; 257/320; 257/321

(57) ABSTRACT

A non-volatile memory having a plurality of gate structures, a plurality of charge storage layers and two doped regions is provided. The gate structures are disposed on the substrate and connected in series. The charge storage layers are disposed between every two neighboring gate structures respectively. The gate structures and the charge storage layers form a memory cell column. The two doped regions are disposed in the substrate at both sides of the memory cell column.

### CROSS-REFERENCE TO RELATED APPLICATION

This application claims the priority benefit of Taiwan application serial no. 94139580, filed on Nov. 11, 2005. All disclosure of the Taiwan application is incorporated herein by reference.

### BACKGROUND OF THE INVENTION

1. Field of Invention

The present invention relates to a semiconductor device, and more particularly relates to a non-volatile memory and manufacturing method and operating method thereof.

2. Description of Related Art

Among various non-volatile memory products, the EEPROM has been widely used as a memory device in personal computers and electronic equipments due to the advantages of storing/reading/erasing data multiple times, and the stored data will not be lost when current is cut off.

In a typical EEPROM, the doped polysilicon is used to make the floating gate and the control gate. Additionally, in order to avoid the problem of data error when the typical EEPROM is severely over erased, a select gate is further disposed on the sidewalls of the control gate and the floating gate and above the substrate, so as to form a split-gate structure.

Furthermore, in the conventional art, a charge trapping layer is used to replace the polysilicon floating gate. The charge trapping layer is made of, for example, silicon nitride. The silicon nitride charge trapping layer usually has a silicon oxide layer on its top surface and bottom surface respectively, thus forming an oxide-nitride-oxide (ONO) composite layer. The EEPROM having the split-gate structure is disclosed in the US Patent U.S. Pat. No. 5,930,631. However, the split-gate structure has a memory cell of large size, as it requires a large split-gate region. Therefore, the size of the memory cell is larger than that of the memory cell of the EEPROM having stacked gates, thus causing the so-called problem that the device integrity cannot be increased.

On the other hand, since the NAND-type array is used to connect each memory cell in series, its integrity may be higher than that of the NOR-type array. Therefore, if the split-gate flash memory cell array is made into a NAND-type array structure, the devices will be much more compact. However, as the write and read procedures of the memory cell in the NAND type array is complex and many memory cells in the NAND type array are connected in series, the read current of the memory cell is low, thus leading to the problems that the operation speed of the memory cell is slow, and the device efficiency cannot be increased.

### SUMMARY OF THE INVENTION

Accordingly, it is an object of the present invention to provide a non-volatile memory and manufacturing method and operating method thereof. Such non-volatile memory may store 2-bit data in a single memory cell, thus improving the integrity of the device.

It is another object of the present invention to provide a non-volatile memory and manufacturing method and operating method thereof. Such non-volatile memory can employ the effect of Source-Side Injection for the programming operation, thus raising the programming speed as well as the memory efficiency.

It is yet another object of the present invention to provide a non-volatile memory and manufacturing method and operating method thereof. The manufacture process of such non-volatile memory is simple, thus reducing the manufacturing cost.

The present invention provides a non-volatile memory, including a plurality of gate structures, a plurality of charge storage layer and two doped regions. The gate structures are formed on the substrate in series. A plurality of charge storage layers are formed between two neighboring gate structures respectively. The charge storage layers and the gate structures constitute the memory cell column, wherein the charge storage layers are arranged in pairs. Two doped regions are formed in the substrate next to the memory cell column.

In the non-volatile memory described above, the gate structure includes a plurality of first gate structures and a plurality of second gate structures. A plurality of first gate structures are formed on the substrate, and two neighboring first gate structures are provided with a gap therebetween. A plurality of second gate structures is formed between the first gate structures, and fills up the gaps.

In the non-volatile memory described above, the charge storage layers are formed as spacers on the sidewalls of the first gate structures.

In the non-volatile memory described above, the charge storage layers are formed in an “L” shape on the sidewalls of the first gate structures.

In the non-volatile memory described above, the charge storage layers and the gate structures are provided with a first dielectric layer therebetween respectively. The material of the first dielectric layer includes silicon oxide.

In the non-volatile memory described above, the charge storage layers and the substrate are provided with a second dielectric layer therebetween respectively. The material of the second dielectric layers includes silicon oxide.

In the non-volatile memory described above, each of the first gate structures includes a first gate dielectric layer formed on the substrate, a first gate formed on the first gate dielectric layer and a cap layer formed on the first gate. Each of the second gate structures includes a second gate dielectric layer formed on the substrate and a second gate formed on the second gate dielectric layer. The material of the first gate dielectric layer and the second gate dielectric layer includes silicon oxide. The material of the first gate and second gate includes doped polysilicon.

In the non-volatile memory described above, the material of the charge storage layers includes silicon nitride or doped polysilicon.

In the non-volatile memory of the present invention, as the gate structures (the first and second gate structures) and the charge storage layers are connected together in series without any gaps therebetween to form a memory cell column, thus improving the integrity of the memory cell column. Moreover, the charge storage layers between the gate structures (the first and second gate structures) can store 1-bit data.

Furthermore, the gate length of the second gate structures depends on the gap distance between the first gate structures. Therefore, the gate length of the second gate structures can be reduced by reducing the gap distance between the first gate structures, thus increasing the device integrity.

In addition, if the charge storage layers have an L-shaped section, and part of the charge storage layers is between the second gate structures and the substrate, a vertical electrical field will be generated between the second gate structures and the substrate during the erasing operation of the non-volatile memory, thereby improving the erase efficiency.

The present invention provides a method for manufacturing a non-volatile memory. A substrate is firstly provided. A plurality of first gate structures is formed on the substrate, and the two neighboring first gate structures have a gap therebetween. A plurality of charge storage layers are formed on the sidewalls of the first gate structures after a tunneling dielectric layer is formed on the substrate. A plurality of second gate structures is formed on the substrate, and fills up the gaps between the first gate structures. The charge storage layers, second gate structures and first gate structures constitute a memory cell column. Then, two doped regions are formed in the substrate next to the memory cell column.

In the method for manufacturing a non-volatile memory described above, the steps of forming the first gate structures on the substrate include forming a first gate dielectric layer on the substrate; then forming a first conductive layer on the first gate dielectric layer; forming a cap layer on the first conductive layer; and patterning the cap layer, first conductive layer and the first gate dielectric layer.

In the method for manufacturing a non-volatile memory described above, the material of the first gate dielectric layer includes silicon oxide.

In the method for manufacturing a non-volatile memory described above, the steps of forming a plurality of charge storage layers on the sidewalls of the first gate structures include forming a first dielectric layer and a charge storage material layer on the substrate; then removing part of the first dielectric layer and part of the charge storage material layer through an anisotropic etching process. The material of the charge storage layers includes silicon nitride.

The method for manufacturing a non-volatile memory described above further includes patterning the charge storage layers to form a plurality of charge storage blocks after the step of forming the charge storage layers on the sidewalls of the first gate structures. The material of the charge storage blocks includes silicon nitride or doped polysilicon.

In the method for manufacturing a non-volatile memory described above, the steps of forming a plurality of charge storage layers on the sidewalls of the first gate structures include forming a first dielectric layer and a charge storage material layer on the substrate; forming a sacrificial layer on the substrate; then removing part of the sacrificial layer through the anisotropic etching process, and forming a plurality of spacers on the surface of the charge storage material layer; removing part of the charge storage material layer and part of the first dielectric layer by using the spacers as masks to expose the substrate; and removing the spacers.

In the method for manufacturing a non-volatile memory described above, the charge storage layers are “L” shaped. The material of the charge storage layers includes silicon nitride.

The method for manufacturing a non-volatile memory described above further includes patterning the charge storage layers to form a plurality of charge storage blocks after the step of forming the charge storage layers on the sidewalls of the first gate structures. The material of the charge storage blocks includes silicon nitride or doped polysilicon.

In the method for manufacturing a non-volatile memory described above, the material of the tunneling dielectric layer includes silicon oxide.

In the method for manufacturing a non-volatile memory described above, the steps of forming the second gate structures on the substrate include forming a second dielectric layer on the substrate; forming a second conductive layer on the second gate dielectric layer, filling up the gaps; and removing part of the second conductive layer until the first gate structures are exposed.

In the method for manufacturing a non-volatile memory described above, the method for removing part of the second conductive layer includes the chemical mechanical polishing process. The material of the second gate dielectric layer includes silicon oxide.

In the method for manufacturing a non-volatile memory described above, the material of the first conductive layer and second conductive layer includes doped polysilicon.

According to the method for manufacturing a non-volatile memory of the present invention, the integrity of the memory array can be improved, since the first gate structures, the charge storage layers and the second gate structures are connected together in series without any gaps therebetween. Furthermore, the steps of forming the non-volatile memory of the present invention are simply, compared with the conventional process, thus reducing the manufacturing cost.

The present invention provides a method for operating the non-volatile memory suitable for a memory cell array. The memory cell array includes a plurality of memory cell columns, a first source/drain region and a second source/drain region formed in the substrate next to the memory cell column respectively, and a plurality of word lines connecting the gate structures in the same row. Each of the memory cell columns has a plurality of gate structures formed on the substrate in series and a plurality of charge storage layers formed between the gate structures respectively, wherein the charge storage layers are arranged in pairs. The method includes in the programming operation, applying a first voltage to a selected word line; applying a second voltage to other non-selected word lines; applying a third voltage to the first source/drain region of the selected memory cell column, and applying a fourth voltage to the second source/drain region of the selected memory cell column. The first voltage is higher than or equal to the threshold voltage of the gate structures. The second voltage is higher than the first voltage. The fourth voltage is higher than the third voltage, so that the charge storage layer adjacent to the selected word line and on the side of the second source/drain region is programmed by the effect of Source-Side Injection.

In the method for operating the non-volatile memory described above, the first voltage is about 1.5 V; the second voltage is about 7 V; the third voltage is about 0 V, and the fourth voltage is about 2.5 V.

In the method for operating the non-volatile memory described above, in the erase operation, a fifth voltage is applied to the word lines and a sixth voltage is applied to the substrate so as to introduce the electrons stored in the charge storage layers to the substrate, wherein the voltage difference between the fifth voltage and sixth voltage may cause FN tunneling effect.

In the method for operating the non-volatile memory described above, the voltage difference is about −12 to −20V. The fifth voltage is 0 V and the sixth voltage is 12 V.

In the method for operating the non-volatile memory described above, in the read operation, a seventh voltage is applied to a selected word line; an eighth voltage is applied to the non-selected word lines; a ninth voltage is applied to the first source/drain region of the selected memory cell column; a tenth voltage is applied to the second source/drain region of the selected memory cell column, so as to read a charge storage layer adjacent to the selected word line and on the side of the second source/drain region, wherein the ninth voltage is higher than the tenth voltage; the seventh voltage is higher than or equal to the threshold voltage of the gate structures, but lower than the voltage difference between the ninth voltage and the tenth voltage; and the eighth voltage is higher than the seventh voltage.

In the method for operating the non-volatile memory described above, the seventh voltage is about 3.5 V; the eighth voltage is about 7 V; the ninth voltage is about 1.5 V; and the tenth voltage is about 0 V.

The method for operating the non-volatile memory described above includes, in the read operation, applying an eleventh voltage to a selected word line; applying a twelfth voltage to other non-selected word lines; applying a thirteenth voltage to the second source/drain region of the selected memory cell column; applying a fourteenth voltage to the first source/drain region of the selected memory cell column, so as to read the charge storage layer adjacent to the selected word line and on the side of the second source/drain region, wherein the thirteenth voltage is higher than the fourteenth voltage; the eleventh voltage is higher than or equal to the threshold voltage of the gate structures, but lower than the voltage difference between the thirteenth voltage and the fourteenth voltage; and the twelfth voltage is higher than the eleventh voltage.

In the method for operating the non-volatile memory described above, the eleventh voltage is about 3.5 V; the twelfth voltage is about 7 V; the thirteenth voltage is about 1.5 V; and the fourteenth voltage is about 0 V.

In the method for operating the non-volatile memory in the present invention, the effect of Source-Side Injection is used for programming the memory cell in the unit of single bit of single memory cell, and the FN tunneling effect is used for erasing the memory cell. Hence, the efficiency of electron injection is high, thus reducing the current of the memory cell during the operation, and improving the operation speed at the same time. Therefore, the current consumption is low, and the power consumption of the whole chip may be reduced effectively.

The present invention provides a method for operating the non-volatile memory suitable for the memory cell array. The memory cell array includes a plurality of memory cell columns, a first source/drain region and a second source/drain region formed in the substrate next to the memory cell column respectively, a plurality of word lines connecting the first gate structures in the same row, and a plurality of select gate lines connecting the second gate structures in the same row. Each of the memory cell columns has a plurality of first gate structures formed on a substrate, in which two neighboring first gate structures have a gap therebetween respectively; a plurality of second gate structures formed in the gaps between the first gate structures; and a plurality of charge storage layers formed between the first gate structures and second gate structures respectively, wherein each of the charge storage layers includes a portion sandwiched between the first gate structure and the substrate. The method includes in the programming operation, applying a first voltage to a selected word line; applying a second voltage to other non-selected word lines and the select gate lines; applying a third voltage to the first source/drain region of the selected memory cell column; and applying a fourth voltage to the second source/drain region of the selected memory cell column, wherein the first voltage is higher than or equal to the threshold voltage of the first gate structures; the second voltage is higher than the first voltage; the fourth voltage is higher than the third voltage, so that the charge storage layer adjacent to the selected word line and on the side of the second source/drain region is programmed by the effect of Source-Side Injection.

In the method for operating the non-volatile memory described above, the first voltage is about 1.5 V; the second voltage is about 9 V; the third voltage is about 0 V and the fourth voltage is about 3.5 V.

In the method for operating the non-volatile memory described above, in the programming operation, a fifth voltage is applied to a selected word line; a sixth voltage is applied to other non-selected word lines and select gate lines; a seventh voltage is applied to the second source/drain region of the selected memory cell column and an eighth voltage is applied to the first source/drain region of the selected memory cell column, wherein the fifth voltage is higher than or equal to the threshold voltage of the first gate structures; the sixth voltage is higher than the fifth voltage; and the eighth voltage is higher than the seventh voltage, so that the charge storage layer adjacent to the selected word line and on the side of the first source/drain region is programmed by the effect of Source-Side Injection.

In the method for operating a non-volatile memory described above, the fifth voltage is about 1.5 V; the sixth voltage is about 9 V; the seventh voltage is about 0 V, and the eighth voltage is about 3.5 V.

In the method for operating the non-volatile memory described above, in the erase operation, a ninth voltage is applied to the word lines and the select gate lines and a tenth voltage is applied to the substrate, so as to introduce the electrons stored in the charge storage layers to the substrate, wherein the voltage difference between the ninth voltage and tenth voltage may cause FN tunneling effect.

In the method for operating a non-volatile memory described above, the voltage difference is about −12 to −20V. The ninth voltage is 0 V, and the tenth voltage is 12 V.

In the method for operating a non-volatile memory described above, in the read operation, an eleventh voltage is applied to the selected word line; a twelfth voltage is applied to other non-selected word lines and the select gate lines; a thirteenth voltage is applied to the first source/drain region of the selected memory cell column; and a fourteenth voltage is applied to the second source/drain region of the selected memory cell column, so that the charge storage layer adjacent to the selected word line and on the side of the second source/drain region is read, wherein the thirteenth voltage is higher than the fourteenth voltage; the eleventh voltage is higher than or equal to the threshold voltage of the gate structures before the charge storage layer is programmed, but lower than the threshold voltage of the gate structures after the charge storage layer is programmed; and the twelfth voltage is higher than the eleventh voltage.

In the method for operating a non-volatile memory described above, the eleventh voltage is about 2.5 V; the twelfth voltage is about 6 V; the thirteenth voltage is about 1.5 V; and the fourteenth voltage is about 0 V.

In the method for operating a non-volatile memory described above, in the read operation, a fifteenth voltage is applied to a selected word line; a sixteenth voltage is applied to other non-selected word lines and the select gate lines; a seventeenth voltage is applied to the second source/drain region of the selected memory cell column; and an eighteenth voltage is applied to the first source/drain region of the selected memory cell column, so as to read the charge storage layer adjacent to the selected word line and on the side of the second source/drain region, wherein the seventeenth voltage is higher than the eighteenth voltage; the fifteenth voltage is higher than or equal to the threshold voltage of the gate structures before the charge storage layer is programmed, but lower than the threshold voltage of the gate structures after the charge storage layer is programmed; and the sixteenth voltage is higher than the fifteenth voltage.

In the method for operating a non-volatile memory described above, the fifteenth voltage is about 2.5 V; the sixteenth voltage is about 6 V; the seventeenth voltage is about 1.5 V, and the eighteenth voltage is about 0 V.

In the method for operating the non-volatile memory in the present invention, the effect of Source-Side Injection is used for programming the memory cell in the unit of single bit of single memory cell, and the FN tunneling effect is used for erasing the memory cell. Hence, the efficiency of electron injection is high, reducing the current of the memory cell during the operation, and improving the operation speed at the same time. Therefore, the current consumption is low, and the power consumption of the whole chip can be reduced effectively.

In order to the make the aforementioned and other objects, features and advantages of the present invention comprehensible, the preferred embodiments accompanied with drawings are described in detail below.

### BRIEF DESCRIPTION OF THE DRAWINGS

FIG. 1A depicts a top view of a preferred embodiment of the non-volatile memory according to the present invention;

FIG. 1B depicts a structural sectional view of a preferred embodiment of the non-volatile memory according to the present invention;

FIG. 1C depicts a structural sectional view of another preferred embodiment of the non-volatile memory according to the present invention;

FIG. 2A depicts a schematic view of an embodiment of the programming operation of the non-volatile memory according to the present invention;

FIG. 2B depicts a schematic view of an embodiment of the read operation of the non-volatile memory according to the present invention;

FIG. 2C depicts a schematic view of another embodiment of the read operation of the non-volatile memory according to the present invention;

FIG. 2D depicts a schematic view of an embodiment of the erase operation of the non-volatile memory according to the present invention;

FIG. 3A depicts a schematic view of an embodiment of the programming operation of the non-volatile memory according to the present invention;

FIG. 3B depicts a schematic view of an embodiment of the programming operation of the non-volatile memory according to the present invention;

FIG. 3C depicts a schematic view of an embodiment of the read operation of the non-volatile memory according to the present invention;

FIG. 3D depicts a schematic view of another embodiment of the read operation of the non-volatile memory according to the present invention;

FIG. 3E depicts a schematic view of an embodiment of the erase operation of the non-volatile memory according to the present invention;

FIGS. 4A to 4D depict the sectional views of the manufacturing flow chart of a preferred embodiment of the non-volatile memory according to the present invention;

FIGS. 5A to 5D depict the sectional views of the manufacturing flow chart of a preferred embodiment of the non-volatile memory according to the present invention.

### DESCRIPTION OF EMBODIMENTS

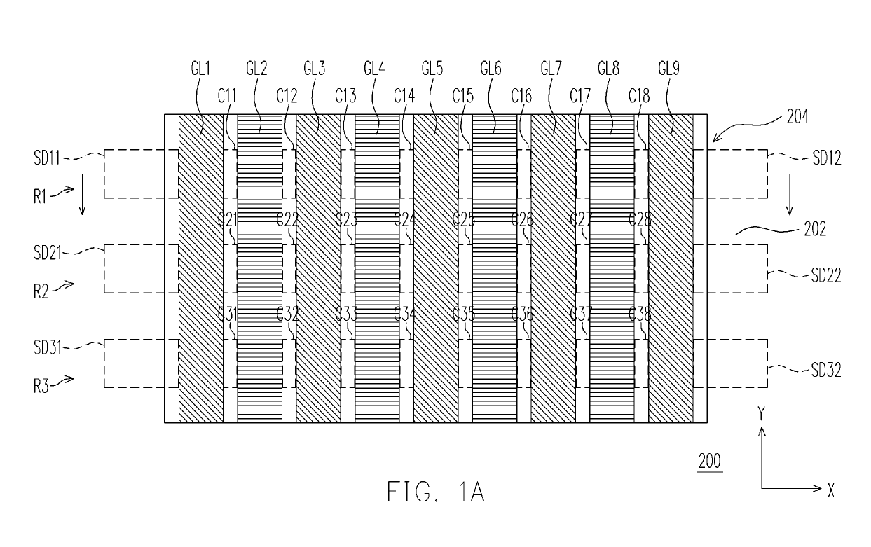

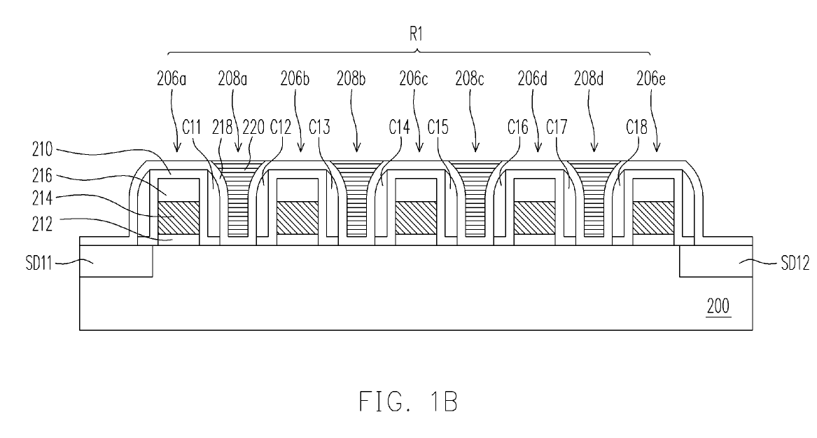

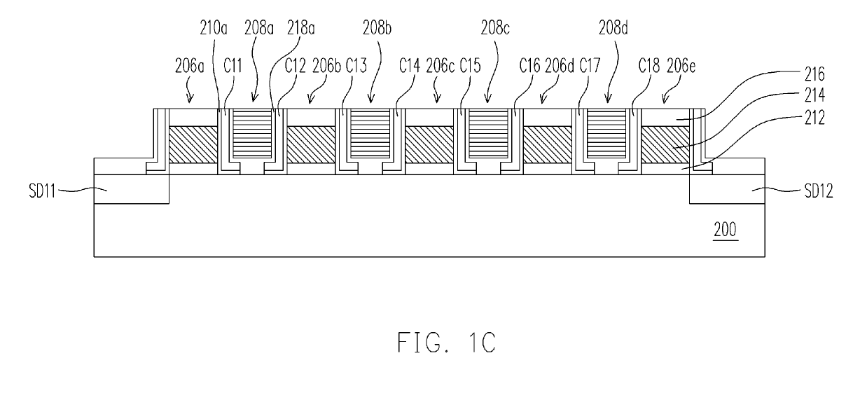

FIG. 1A depicts a top view of a preferred embodiment of the non-volatile memory according to the present invention. FIG. 1B depicts a structural sectional view of a preferred embodiment of the non-volatile memory according to the present invention, and FIG. 1B depicts the section taken along line A-A′ of FIG. 1A.

Referring to FIG. 1A, the non-volatile memory array of the present invention includes a substrate 200, a plurality of gate lines GL1-GL9, a plurality of charge storage layers C11-C38 and a plurality of source/drain regions SD11-SD32.

The substrate 200 is, for example, a silicon substrate. At least a device isolation structure 202 is, for example, formed on the substrate 200 to define active regions 204. The active regions 204 are, for example, strip-like, and extend in the direction X. A plurality of gate lines GL1-GL9 are formed on the substrate 200, and arranged, for example, in parallel, and extend in the direction Y. The intersections of the gate lines GL1-GL9 and the active regions 204 are formed as, for example, the gate structures. The charge storage layers C11-C38 are, for example, formed between two neighboring gate structures. In the direction X (column direction), the gate structures on the active region 204 and the charge storage layers C11-C38 are connected together in series without any gaps to constitute the memory cell columns R1-R3. In the direction Y (row direction), the gate structures on the active regions 204 are connected in series by the gate lines GL1-GL9. The source/drain regions SD11-SD32 are, for example, formed in the substrate 200 next to the memory cell columns R1-R3.

Then, the structure of the non-volatile memory according to the present invention is illustrated by taking the memory cell column R1 as an example.

Referring to FIGS. 1A and 1B, the structure of the non-volatile memory according to the present invention includes a substrate 200, a plurality of first gate structures 206a-206e, a plurality of second gate structures 208a-208d (a plurality of gate structures constituted by a plurality of gate lines GL1-GL9, including the first gate structures 206a-206e and second gate structures 208a-208d), a plurality of charge storage layers C11-C18, dielectric layers 210, a source/drain region SD11 and a source/drain region SD12.

The substrate 200 is, for example, a silicon substrate. The substrate 200 can be a P-type substrate or a N-type substrate. The device isolation structures 202 are formed in the substrate 200 for defining the active regions 204.

The first gate structures 206a-206e are formed on the substrate 200, and each of them includes, for example, a gate dielectric layer 212, a gate 214 and a cap layer 216 respectively. The gate dielectric layer 212 is formed, for example, on the substrate 200. The gate 214 is formed, for example, on the gate dielectric layer 212. The cap layer 216 is formed, for example, on the gate 214. The gate dielectric layer 212 is made of, for example, silicon oxide. The gate 214 is made of, for example, doped polysilicon. The cap layer 216 is made of, for example, silicon oxide.

The second gate structures 208a-208d are formed on the substrate 200 and between the neighboring first gate structures 206a-206e. Each of the second gate structures 208a-208d includes, for example, a gate dielectric layer 218 and a gate 220 respectively. The gate dielectric layer 218 is formed, for example, on the substrate 200. The gate 220 is formed, for example, on the gate dielectric layer 218. The gate dielectric layer 218 is made of, for example, silicon oxide. The gate 220 is made of, for example, doped polysilicon.

A plurality of charge storage layers C11-C18 are formed, for example, between the first gate structures 206a-206e and second gate structures 208a-208d respectively. Furthermore, the charge storage layers are arranged in pairs between the neighboring first gate structures 206a-206e. The material of the charge storage layers C11-C18 includes conductor material (for example, doped polysilicon) or charge trapping material (for example, silicon nitride). When the charge storage layers C11-C18 are made of doped polysilicon, the charge storage layers C11-C18 are, for example, block shape, and only between the first gate structures 206a-206e and second gate structures 208a-208d on the active region 204. When the charge storage layers C11-C18 are made of silicon nitride, the charge storage layers C11-C18 are, for example, strip-like, i.e. the charge storage layers C11, C21 and C31 are one silicon nitride layer without being cut off from each other. The charge storage layers C11-C18 are located between the whole gate lines GL1-GL9. The charge storage layers C11-C18 can be formed as spacers on the sidewalls of the first gate structures 206a-206e. The gate dielectric layers 218 between the charge storage layers C11-C18 and gates 220 are used as isolation layers for isolating the charge storage layers C11-C18 from the gates 220.

The dielectric layers 210 are formed, for example, between the first gate structures 206a-206e and the charge storage layers C11-C18 and between the substrate 200 and the charge storage layers C11-C18. The dielectric layers 210 between the first gate structures 206a-206e and the charge storage layers C11-C18 are used as the isolation layers for isolating the first gate structures 206a-206e from the charge storage layers C11-C18. The dielectric layers 210 between the substrate 200 and charge storage layers C11-C18 are used as the tunneling dielectric layers. The dielectric layer 210 is made of, for example, silicon oxide.

The first gate structures 206a-206e, second gate structures 208a-208d and the charge storage layers C11-C18 are connected together without any gaps therebetween to constitute the memory cell column R1.

The source/drain region SD11 and source/drain region SD12 are formed, for example, in the substrate 200 next to the memory cell column R1 respectively. The source/drain region SD11 and source/drain region SD12 are, for example, n-type doped regions or p-type doped regions.

In the above mentioned non-volatile memory, the first gate structures 206a-206e, second gate structures 208a-208d and the charge storage layers C11-C18 are connected together in series without any gaps therebetween to constitute the memory cell column R1, so the integrity of the memory cell column may be raised. Moreover, the charge storage layers C11-C18 between the first gate structures 206a-206e and the second gate structures 208a-208d can store 1-bit data.

Furthermore, the gate length of the second gate structures 208a-208d depends on the gap distance between the first gate structures 206a-206e, so the gate length of the second gate structures 208a-208d can be reduced by reducing the gap distance of the first gate structures 206a-206e, thus increasing the integrity of the device.

FIG. 1C depicts a structural sectional view of another preferred embodiment of the non-volatile memory according to the present invention, and FIG. 1C depicts the section taken along line A-A′ of FIG. 1A. In FIG. 1C, the means same as that of FIGS. 1A and 1B will be indicated by the same numerals and omitted in description, while only the difference is illustrated herein.

Referring to FIG. 1C, the difference between the non-volatile memory of the present embodiment and the non-volatile memory of FIG. 1B resides in that the sections of the charge storage layers C11-C18 are “L” shape, i.e. part of the charge storage layers C11-C18 are respectively located between the second gate structures 208a-208d and the substrate 200. The gate dielectric layers 218a between the charge storage layers C11-C18 and gates 220 are used as the isolation layers for isolating the charge storage layers C11-C18 from the gates 220.

The dielectric layers 210a are formed, for example, between the first gate structures 206a-206e and the charge storage layers C11-C18 and between the substrate 200 and the charge storage layers C11-C18. The dielectric layers 210a between the first gate structures 206a-206e and the charge storage layers C11-C18 are used as isolation layers for isolating the first gate structures 206a-206e from the charge storage layers C11-C18. The dielectric layer 210a between the substrate 200 and the charge storage layers C11-C18 are used as tunneling dielectric layers. The dielectric layers 210a are made of, for example, silicon oxide.

In the abovementioned non-volatile memory, since part of the charge storage layers C11-C18 are respectively located between the second gate structures 208a-208d and the substrate 200, and the charge is stored in part of the charge storage layers C11-C18 between the second gate structures 208a-208d and substrate 200, during the erase operation of the non-volatile memory of the present embodiment, the erase efficiency may be raised by the vertical electrical field generated between the second gate structures 208a-208d and substrate 200.

In the abovementioned embodiment, 9 gate structures and 8 charge storage layers connected in series are taken as an example. Definitely, the number of gate structures and charge storage layers connected in series of the present invention can be determined according to the actual requirements, for example, one memory cell column may be connected in series of 33 to 65 gate structures and 32 to 64 charge storage layers.

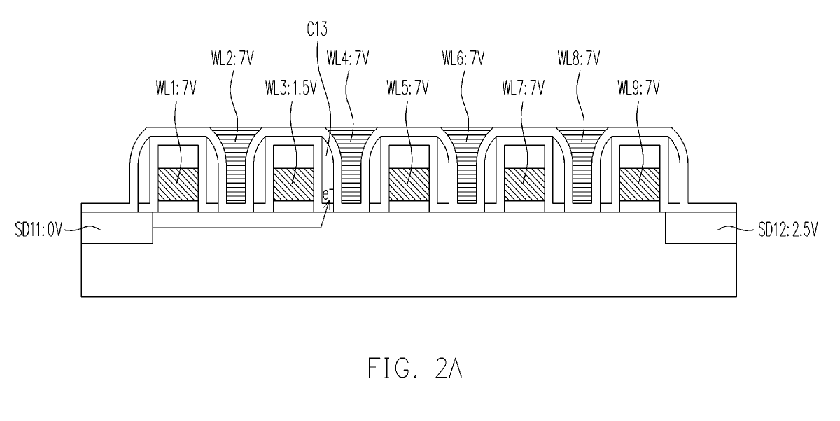

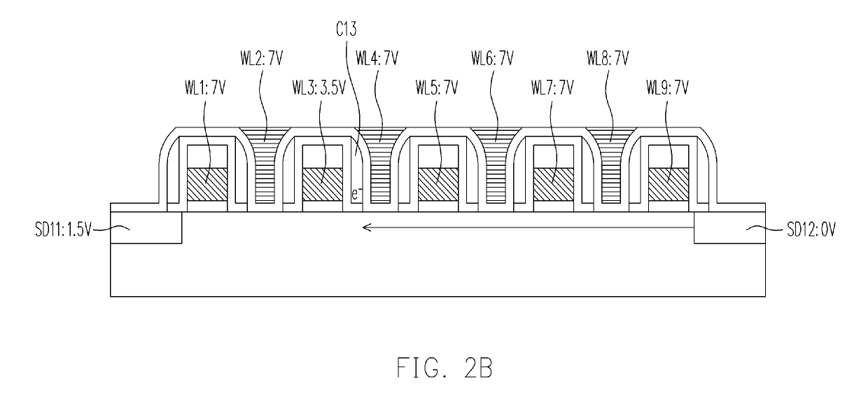

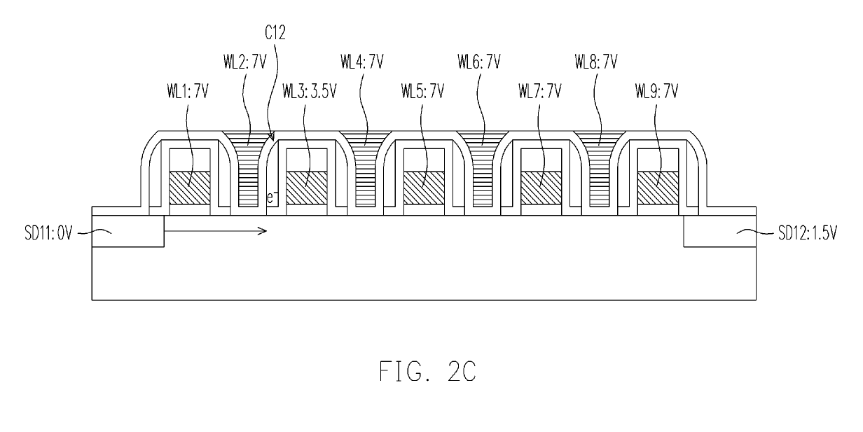

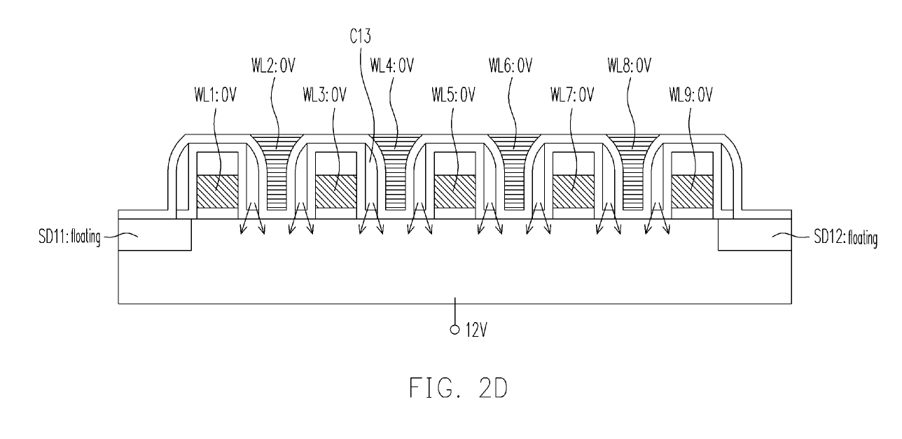

Then, the operation mode of the preferred embodiment of non-volatile memory according to the present invention is described. FIG. 2A is a schematic view of an embodiment of the programming operation of the non-volatile memory according to the present invention. FIG. 2B is a schematic view of an embodiment of the read operation of the non-volatile memory according to the present invention. FIG. 2C is a schematic view of another embodiment of the read operation of the non-volatile memory according to the present invention. FIG. 2D is a schematic view of an embodiment of the erase operation of the non-volatile memory according to the present invention.

The operation method of the non-volatile memory in the present invention will be illustrated only by a preferred embodiment below, but the operation methods of the non-volatile memory in the present invention are not limited to these. The present embodiment is described by taking the non-volatile memory of FIG. 1A and FIG. 1B as an example. Moreover, as the gate lines GL1-GL9 are used as word lines in the present embodiment, the gate lines GL1-GL9 are represented by word lines WL1-WL9 in FIGS. 2A to 2D. The charge storage layer C13 is taken as the example in all descriptions below.

Referring to FIG. 2A, storing electrons into the charge storage layer C13 is taken as an example in the programming operation. The voltage Vp1, for example, about 2.5 V, is applied to the selected word line WL3 on the side of the selected source/drain region SD11 of the charge storage layer C13 and adjacent to the selected charge storage layer C13 in the selected memory cell column R1. The voltage Vp2, for example, about 7 V, is applied to the non-selected word lines WL1-WL2 and WL4-WL9. The voltage Vp3, for example, about 2.5 V, is applied to the source/drain region SD12 of the selected memory cell column R1. The voltage Vp4, for example, about 0 V, is applied to the source/drain region SD11 of the selected memory cell column R1. The voltage Vp1 is higher than or equal to the threshold voltage of the gate structure. The voltage Vp2 is higher than voltage Vp1. The voltage Vp3 is higher than voltage Vp4, so that the selected charge storage layer C13 on the side of the source/drain region SD12 of the selected word line WL3 is programmed by the effect of Source-Side Injection.

In the above mentioned programming operation, the effect of Source-Side Injection is used in the programming operation, and thus the programming efficiency is high and the programming time is reduced. Moreover, in the programming method described above, the charge storage layers are preferably sequentially programmed from the source of the memory cell column, when programming each charge storage layer in the memory cell column. For example, the memory cell column R1 can be programmed according to the sequence as charge storage layer C18, C17, C16 . . . C11, such that the interference to the programming caused by the partial electrons stored in the charge trapping layer can be avoided, and the programming efficiency is improved.

Referring to FIG. 2B, the voltage Vr1, for example, about 3.5 V, is applied to the selected word line WL3 on the side of the source/drain region SD11 of the selected charge storage layer C13 and adjacent to the selected charge storage layer C13 in the selected memory cell column R1, when reading the charge storage layer C13. The voltage Vr2, for example, about 7 V, is applied to other non-selected word lines WL1-WL2 and WL4-WL9. The voltage Vr3, for example, about 0 V, is applied to the source/drain region SD12 of the selected memory cell column R1. The voltage Vr4, for example, about 1.5 V, is applied to the source/drain region SD11 of the selected memory cell column R1. The voltage Vr4 is higher than the voltage Vr3. The voltage Vr1 is higher than or equal to the threshold voltage of the gate structure but lower than the voltage difference between voltage Vr4 and voltage Vr3. The voltage Vr2 is higher than the voltage Vr1. As the total charge in the charge storage layer is negative, the channel below the charge storage layer is off and the current is low; while as the total charge in the charge storage layer is positive, the channel below the charge storage layer is on and the current is high, and thus it can be determined whether the digital information stored in the charge storage layer is “11” or “0” by the status of ON/OFF and high/low current of the channel below the charge storage layer.

Referring to FIG. 2C, another method for the read operation of the present invention is illustrated. The voltage Vr5, for example, about 3.5 V, is applied to the selected word line WL3 on the side of the source/drain region SD12 of the selected charge storage layer C12 and adjacent to the selected charge storage layer C12 in the selected memory cell column R1, when reading the charge storage layer C12. The voltage Vr6, for example, about 7 V, is applied to other non-selected word lines WL1 and WL3-WL9. The voltage Vr7, for example, about 0 V, is applied to the source/drain region SD11 of the selected memory cell column R1. The voltage Vr8, for example, about 1.5V is applied to the source/drain region SD12 of the selected memory cell column R1. The voltage Vr8 is higher than voltage Vr7. The voltage Vr1 is higher than or equal to the threshold voltage of the gate structures but lower than the voltage difference between voltage Vr8 and voltage Vr7. The voltage Vr6 is higher than voltage Vr5. As the total charge in the charge storage layer is negative, the channel below the charge storage layer is off and the current is lower; while as the total charge in the charge storage layer is positive, the channel below the charge storage layer is on and the current is high, and thus it can be determined whether the digital information stored in the charge storage layer is “1” or “0” by the status of ON/OFF and high/low current of the channel below the charge storage layer.

Referring to FIG. 2D, the voltage Ve1 is applied to the word lines WL1-WL9, and the voltage Ve2 is applied to the substrate when erasing, so that the source/drain region SD11 and the source/drain region SD12 are floating, and the electrons stored in the charge storage layer are introduced into the substrate, and thus the data in the memory cell is erased. The voltage difference between voltage Ve1 and voltage Ve2 may cause FN tunneling effect. The voltage difference between voltage Ve1 and voltage Ve2 is, for example, about −12 to −20V. For example, the voltage Ve1 is 0 V and the voltage Ve2 is 12 V.

In the method for operating the non-volatile memory in the present invention, the effect of Source-Side Injection is used for programming the memory cell in the unit of the single bit of the single memory cell, and the FN tunneling effect is used for erasing the memory cell, so that the efficiency of electron injection is high, and thus the current of the memory cell during the operation can be reduced, and the operation speed is improved at the same time. Therefore, the current consumption is low, and the power consumption of the whole chip can be reduced effectively.

The method for operating the non-volatile memory disclosed in the embodiment described above also can be applied in the non-volatile memory in FIG. 1C, besides the non-volatile memory in FIG. 1B.

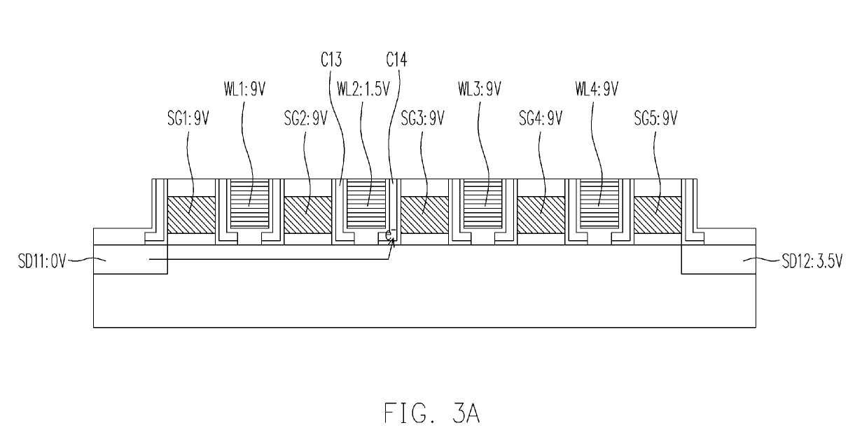

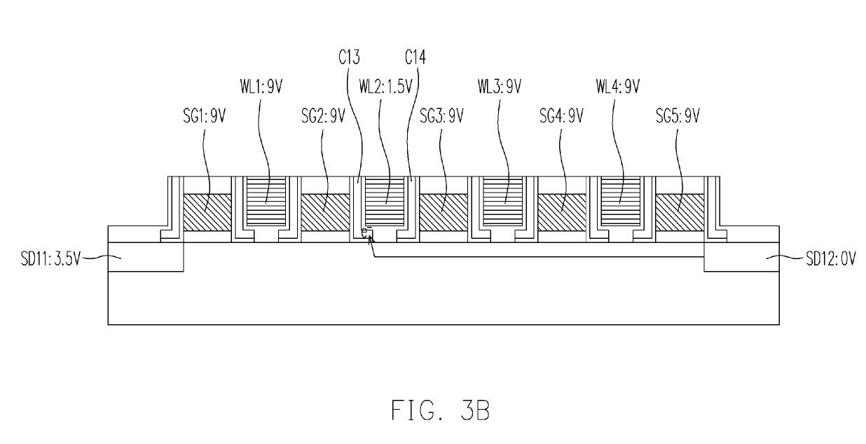

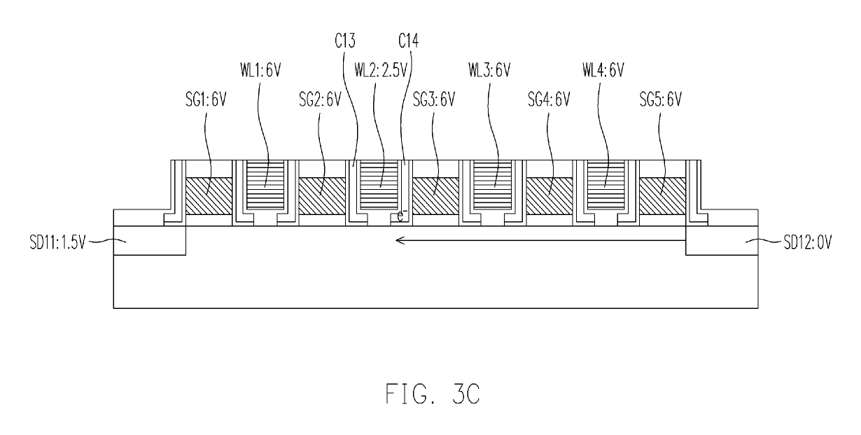

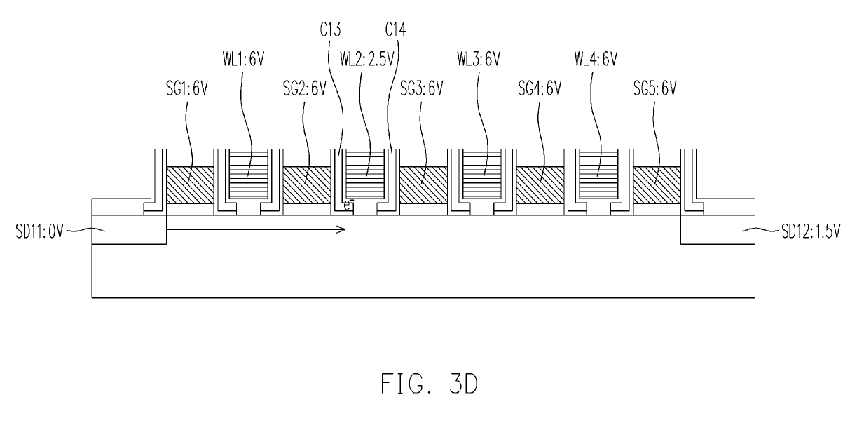

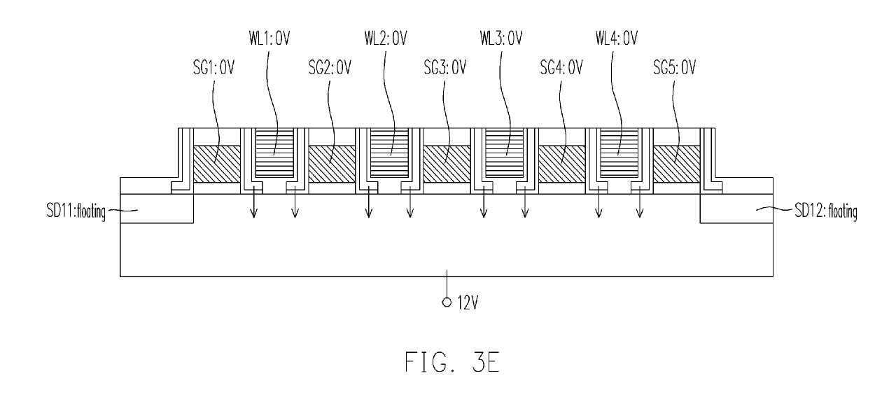

Then, the operation mode of another preferred embodiment of the non-volatile memory according to the present invention is described. FIG. 3A is a schematic view of an embodiment of the programming operation of the non-volatile memory according to the present invention. FIG. 3B is a schematic view of an embodiment of the programming operation of the non-volatile memory according to the present invention. FIG. 3C is a schematic view of an embodiment of the read operation of the non-volatile memory according to the present invention. FIG. 3D is a schematic view of another embodiment of the read operation of the non-volatile memory according to the present invention. FIG. 3E is a schematic view of an embodiment of the erase operation of the non-volatile memory according to the present invention.

The present embodiment is illustrated by taking the non-volatile memory of FIG. 1A and FIG. 1C as an example. Moreover, being used as word lines in the operation method of the present embodiment, the gate lines GL2, GL4, GL6 and GL8 are represented by the word lines WL1-WL4 in FIGS. 2A to 2D. On the other hand, being used as the select gate lines, the gate lines GL1, GL3, GL5, GL7 and GL9 are represented by the select gate lines SG1-SG5.

Referring to FIG. 3A, storing the electrons into the charge storage layer C14 is taken as an example in the programming operation. The voltage Vp1, for example, about 1.5 V, is applied to the selected word line WL2. The voltage Vp2, for example, about 9 V, is applied to the non-selected word lines WL1, WL3, WL4 and the select gate lines SG1-SG5. The voltage Vp3, for example, about 3.5 V, is applied to the source/drain region SD12 of the selected memory cell column R1. The voltage Vp4, for example, about 0 V, is applied to the source/drain region SD11 of the selected memory cell column R1. The voltage Vp1 is higher than or equal to the threshold voltage of the gate structure. The voltage Vp2 is higher than voltage Vp1. The voltage Vp3 is higher than voltage Vp4, so that the selected charge storage layer C14 on the side of the source/drain region SD12 of the selected word line WL2 is programmed by the effect of Source-Side Injection.

Referring to FIG. 3B, storing the electrons into the charge storage layer C13 is taken as an example in the programming operation. The voltage Vp1, for example, about 1.5 V, is applied to the selected word line WL2. The voltage Vp2, for example, about 9 V, is applied to the non-selected word lines WL1, WL3, WL4 and the select gate lines SG1-SG5. The voltage Vp3, for example, about 3.5 V, is applied to the source/drain region SD11 of the selected memory cell column R1. The voltage Vp4, for example, about 0 V, is applied to the source/drain region SD12 of the selected memory cell column R1. The voltage Vp1 is higher than or equal to the threshold voltage of the gate structure. The voltage Vp2 is higher than voltage Vp1. The voltage Vp3 is higher than voltage Vp4, so that the selected charge storage layer C13 on the side of the source/drain region SD11 of the selected word line WL2 is programmed by the effect of Source-Side Injection.

In the programming operation described above, the effect of Source-Side Injection is used for the programming operation, and thus the programming efficiency is high and the programming time is reduced.

Referring to FIG. 3C, the voltage Vr1, for example, about 2.5 V, is applied to the selected word line WL2, when reading the charge storage layer C14. The voltage Vr2, for example, about 6 V, is applied to other non-selected word lines WL1, WL3, WL4 and the select gate lines SG1-SG5. The voltage Vr3, for example, about 1.5 V, is applied to the source/drain region SD11 of the selected memory cell column R1. The voltage Vr4, for example, about 0 V, is applied to the source/drain region SD12 of the selected memory cell column R1. The voltage Vr3 is higher than voltage Vr4. The voltage Vr1 is higher than or equal to the threshold voltage of the gate structure before the charge storage layer C14 is programmed, but lower than the threshold voltage of the gate structure after the charge storage layer C14 is programmed. The voltage Vr2 is higher than voltage Vr1. As the total charge in the charge storage layer is negative, the channel below the charge storage layer is off and the current is low; while as the total charge in the charge storage layer is positive, the channel below the charge storage layer is on and the current is high, and thus it can be determined whether the digital information stored in the charge storage layer is “1” or “0” by the status of ON/OFF and high/low current of the channel below the charge storage layer.

Referring to FIG. 3D, voltage Vr1, for example, about 2.5 V, is applied to the selected word line WL2, when reading the charge storage layer C13. The voltage Vr2, for example, about 6 V, is applied to other non-selected word lines WL1, WL3, WL4 and the select gate lines SG1-SG5. The voltage Vr3, for example, about 1.5 V, is applied to the source/drain region SD12 of the selected memory cell column R1. The voltage Vr4, for example, about 0 V, is applied to the source/drain region SD11 of the selected memory cell column R1. The voltage Vr3 is higher than voltage Vr4. The voltage Vr1 is higher than or equal to the threshold voltage of the gate structure before the charge storage layer C13 is programmed, but lower than the threshold voltage of the gate structure after the charge storage layer C13 is programmed. The voltage Vr2 is higher than voltage Vr1. As the total charge in the charge storage layer is negative, the channel below the charge storage layer is off and the current is low; while as the total charge in the charge storage layer is positive, the channel below the charge storage layer is on and the current is high, and thus it can be determined whether the digital information stored in the charge storage layer is “1” or “0” by the status of ON/OFF and high/low current of the channel below the charge storage layer.

Referring to FIG. 3E, the voltage Ve1 is applied to the word lines WL1-WL4 and the select gate lines SG1-SG5, and the voltage Ve2 is applied to the substrate when erasing, so that the source/drain region SD11 and the source/drain region SD12 are floating, and the electrons stored in the charge storage layer are introduced into the substrate, thus erasing the data in the memory cell. The voltage difference between voltage Ve1 and voltage Ve2 may cause FN tunneling effect. The voltage difference between voltage Ve1 and voltage Ve2 is, for example, about −12 to −20 V. For example, the voltage Ve1 is 0 V and the voltage Ve2 is 12 V.

In the method for operating the non-volatile memory of the present invention, the effect of Source-Side Injection is used for programming the memory cell in the unit of the single bit of the single memory cell, and the FN tunneling effect is used for erasing the memory cell, so that the efficiency of electron injection is high, and thus the current of the memory cell during the operation can be reduced, and the operation speed is improved at the same time. Therefore, the current consumption is low, and the power consumption of the whole chip can be reduced effectively. Furthermore, as part of the charge storage layers C11-C18 are located between the word lines WL1-WL4 and the substrate respectively, the erase efficiency may be raised during the erase operation by the vertical electrical field generated between word lines WL1-WL4 and the substrate.

The method for operating the non-volatile memory disclosed in the embodiment described above can be applied in the non-volatile memory in FIG. 1B, besides the non-volatile memory in FIG. 1C.

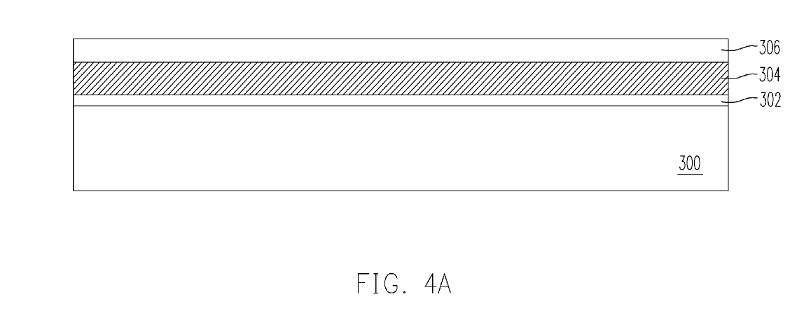

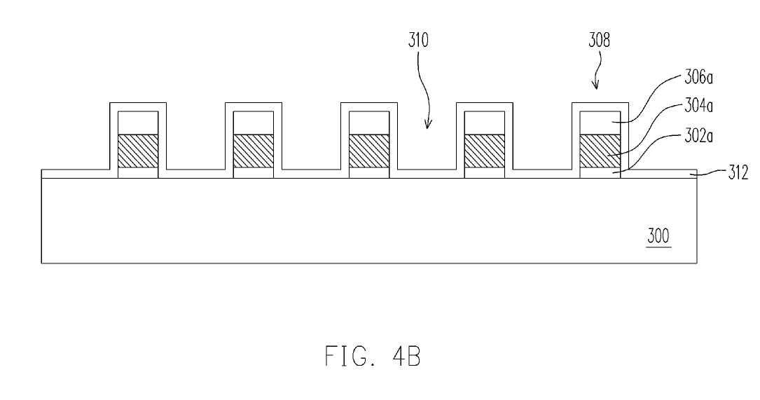

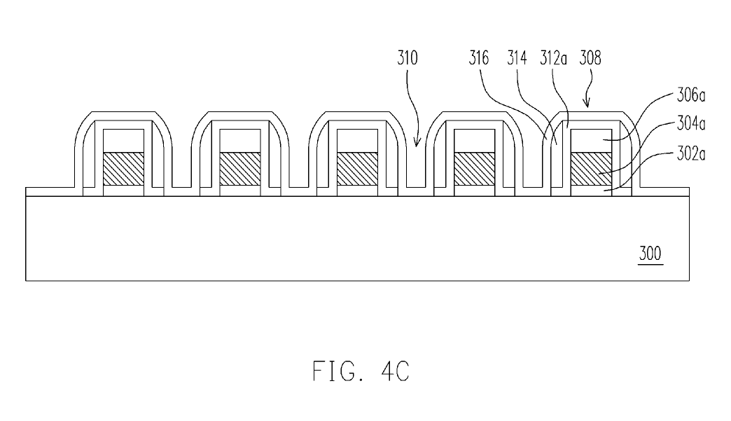

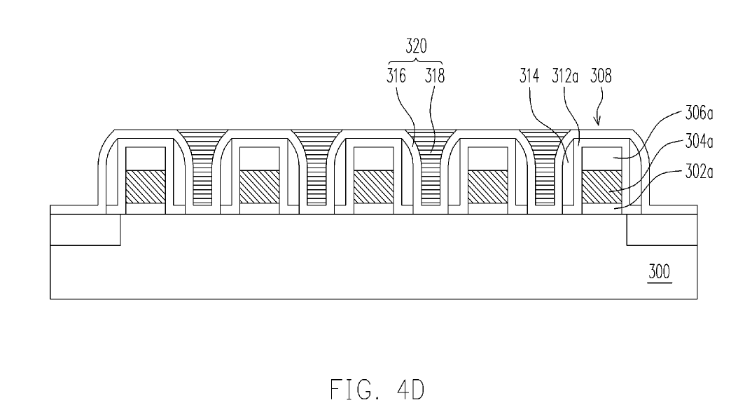

Then, the method for manufacturing the non-volatile memory of the present invention is described. FIGS. 4A to 4D depict the sectional views of the manufacturing flow chart of a preferred embodiment of the non-volatile memory according to the present invention, and show the sections taken along line A-A′ of FIG. 1A. FIGS. 4A to 4D are also the sectional views of the manufacturing flow chart of the non-volatile memory in FIG. 1B.

Firstly, referring to FIG. 4A, a substrate 300 is provided, and the substrate 300 is, for example, a silicon substrate. The device isolation structures (not shown) are formed in the substrate 300 to define the active regions. The method for forming the device isolation structures is, for example, the shallow trench isolation process.

Then, a dielectric layer 302, a conductive layer 304 and a cap layer 306 are formed on the substrate 300. The dielectric layer 302 is made of, for example, silicon oxide, and the forming method is, for example, thermal oxidation. The conductive layer 306 is made of, for example, doped polysilicon. The method of forming the conductive layer 306 is, for example, the ion-implantation step after a non-doped polysilicon layer is formed by the Chemical Vapor Deposition (CVD) process, or the CVD process by means of in-situ doping. The cap layer 306 is made of, for example, silicon oxide, and the forming method thereof is, for example, the CVD process.

Referring to FIG. 4B, the cap layer 306, conductive layer 304 and dielectric layer 302 are patterned to form a plurality of gate structures 308. The method for patterning the cap layer 306, conductive layer 304 and dielectric layer 302 is, for example, lithography techniques. The select gate structure 308 includes, for example, the cap layer 306a, the conductive layer 304a and the dielectric layer 302a. The two neighboring gate structures 308 are provided with a gap 310 therebetween. The conductive layer 304a is, for example, used as a gate, and the dielectric layer 302a is, for example, used as a gate dielectric layer.

Then, another dielectric layer 312 is formed on the substrate 300, and the dielectric layer 312 covers the gate structure 308. The dielectric layer 312 is made of, for example, silicon oxide, and the forming method thereof is, for example, the CVD process.

Referring to FIG. 4C, a charge storage layer 314 is formed on the sidewall of the gate structure 308. The material of the charge storage layer 314 includes the conductor material (for example, doped polysilicon) or the charge trapping material (for example, silicon nitride). The charge storage layer 314 is formed by an anisotropic etching process, after a charge storage material layer is formed. In the step of forming the charge storage layer 314, part of the dielectric layer 312 is removed until the substrate 300 is exposed, so as to form the dielectric layer 312a. The dielectric layer 312a is, for example, between the charge storage layer 314 and the gate structure 308 and between the charge storage layer 314 and the substrate 300. The dielectric layer 312a between the charge storage layer 314 and the gate structure 308 is used as an isolation layer for isolating the charge storage layer 314 from the gate structure 308. The dielectric layer 312a between the charge storage layer 314 and the substrate 300 is used as a tunneling dielectric layer. If the charge storage layer 314 is made of conductor material (for example, doped polysilicon), it is necessary to pattern the charge storage layer 314, so as to cut the charge storage layer 314 into blocks (charge storage block). The charge storage blocks are located, for example, on the active regions. If the charge storage layer 314 is made of charge trapping material (for example, silicon nitride), it is unnecessary to further cut charge storage layer 314 into blocks.

Then, another dielectric layer 316 is formed on the substrate 300, to cover the gate structure 308 and the charge storage layer 314. The dielectric layer 316 is made of, for example, silicon oxide, and the forming method thereof is, for example, the CVD process.

Referring to FIG. 4D, a plurality of conductive layers 318 are formed on the substrate 300, and fill up the gaps 310 between the gate structures 308. The steps for forming the conductive layers 318 include, for example, forming a conductor material layer on the substrate 300, and planarizing through the chemo-mechanical polishing process or etch back process until the dielectric layer 316 is exposed. The conductive layer 318 is made of, for example, doped polysilicon, and the forming method is, for example, the ion-implantation step after a non-doped polysilicon layer is formed by the CVD process, or the CVD process by means of in-situ doping. The conductive layer 318 and the dielectric layer 316 constitute another gate structure 320.

The dielectric layer 316 between the conductive layer layer 318 and the charge storage layer 314 is used as an isolation layer for isolating the charge storage layer 314 from the conductive layer 318. The dielectric layer 316 between the substrate 300 and the conductive layer 318 is used as a gate dielectric layer.

The gate structure 308, charge storage layer 314 and the gate structure 320 are connected in series without any gaps to form a memory cell column. And the source/drain regions 322 and 324 are formed in the substrate 300 next to the memory cell column. The subsequent process for completing the memory array is well known to those skilled in the art, and the unnecessary details are omitted herein.

In the embodiment described above, the gate structure 308, charge storage layer 214 and the gate structure 320 are connected together in series without any gaps, so that the integrity of the memory array may be improved. Furthermore, the steps of forming the non-volatile memory in the present invention are simply compared with the conventional process, and thus the manufacturing cost may be reduced.

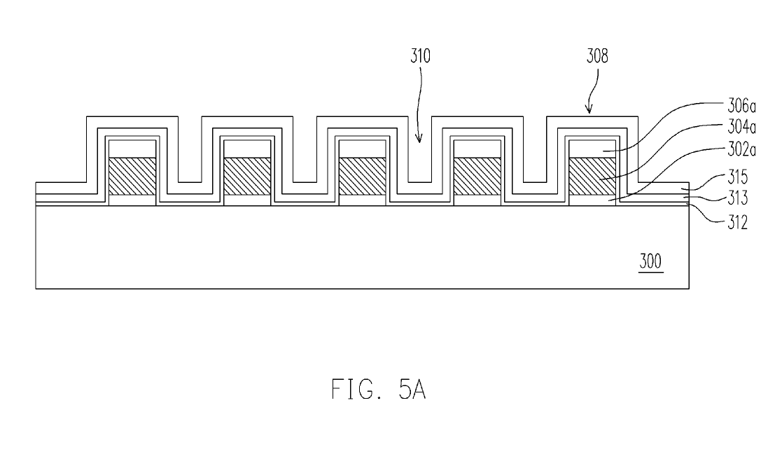

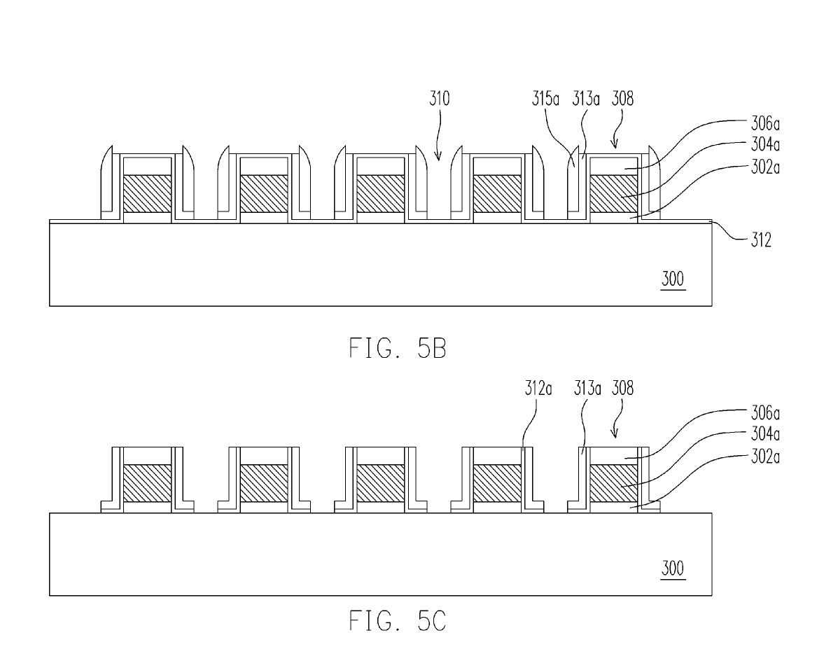

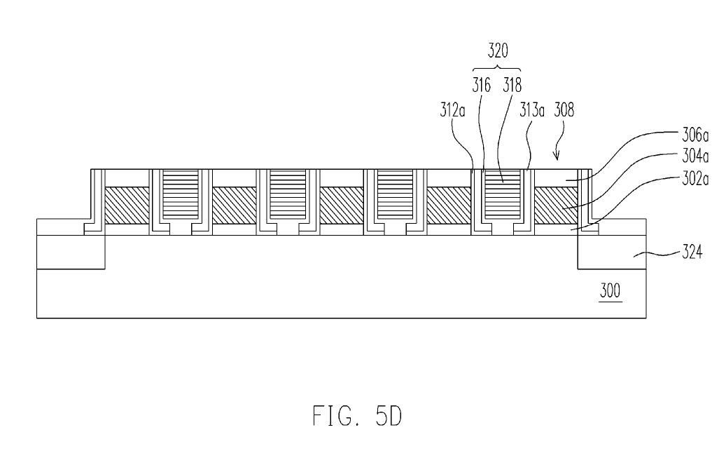

FIGS. 5A to 5D depict the sectional views of the manufacturing flow chart of another embodiment of the non-volatile memory according to the present invention, and show the sections taken along line A-A′ of FIG. 1A, and FIGS. 5A to 5D are also the sectional views of the manufacturing flow chart of the non-volatile memory depicted in FIG. 1C. FIGS. 5A to 5D follow FIG. 4B, and in FIGS. 5A to 5D, the means same as that of FIGS. 4A to 4D will be indicated by the same numerals and will not be described in further details.

Referring to FIG. 5A, after the gate structure 308 and the dielectric layer 312 are formed, a charge storage material layer 313 is formed on the substrate 300. The charge storage material layer 313 is made of conductor material (for example, doped polysilicon) or charge trapping material (for example, silicon nitride). The method for forming the charge storage material layer 313 is, for example, the CVD process.

And then, a sacrificial layer 315 is formed on the substrate 300. The sacrificial layer 315 is made of, for example, the material having a etch selectivity different from the charge storage material layer 313. In the present embodiment, the sacrificial layer 315 is made of, for example, silicon oxide. Definitely, the material of the sacrificial layer 315 can be appropriately changed according to the material of the charge storage layer 313.

Referring to FIG. 5B, part of the sacrificial layer 315 is removed, and the sacrificial layer 315a (silicon isolation wall) is formed on the sidewall of the gate structure 308. The method for removing part of the sacrificial layer 315 is, for example, anisotropic etching.

And then, by using the sacrificial layer 315a (silicon isolation wall) as a mask, part of the charge storage material layer 313 is removed until the dielectric layer 312 is exposed, thus forming the charge storage layer 313a. The method for removing part of the charge storage material layer 313 is, for example, etching. The section of the charge storage layer 313a is, for example, “L” shape.

Referring to FIG. 5C, the sacrificial layer 315a (silicon isolation wall) is removed. And during this forming step, part of the dielectric layer 312 is removed simultaneously until the substrate 300 is exposed, thus forming the dielectric layer 312a. The dielectric layer 312a is located, for example, between the charge storage layer 313a and the gate structure 308 and between the charge storage layer 313a and the substrate 300. The dielectric layer 312a between the charge storage layer 313a and the gate structure 308 is used as an isolation layer for isolating the charge storage layer 314 from the gate structure 308. The dielectric layer 312a between the charge storage layer 313a and the substrate 300 is used as the tunneling dielectric layer.

After removing the sacrificial layer 315a (silicon isolation wall) and part of the dielectric layer 312, if the charge storage layer 313a is made of conductor material (for example, doped polysilicon), it is necessary to pattern the charge storage layer 313a, so as to cut the charge storage layer 313a into blocks (charge storage block). The charge storage blocks are located, for example, on the active regions. If the charge storage layer 313a is made of charge trapping material (for example, silicon nitride), it is unnecessary to further cut the charge storage layer 313a into blocks.

Referring to FIG. 5D, another dielectric layer 316 is formed on the substrate 300. The dielectric layer 316 covers the gate structure 308 and the charge storage layer 314. The dielectric layer 316 is made of, for example, silicon oxide, and the forming method thereof is, for example, the CVD process.

A plurality of conductive layers 318 are formed on the substrate 300, and fill up the gaps 310 between the gate structures 308. The steps of forming the conductive layers 318 include, for example, forming a conductor material layer on the substrate 300, and then planarizing through the chemo-mechanical polishing process or etch back process until the dielectric layer 306a is exposed. The conductive layer 318 is made of, for example, doped polysilicon, and the forming method is, for example, the ion-implantation step after a non-doped polysilicon layer is formed by the CVD process, or the CVD method by means of in-situ doping. The conductive layer 318 and the dielectric layer 316 constitute another gate structure 320.

The dielectric layer 316 between the charge storage layer 313a and the conductive layer 318 is used as an isolation layer for isolating the charge storage layer 313a from the conductive layer 318. The dielectric layer 316 between the substrate 300 and the conductive layer 318 is used as a gate dielectric layer.

The gate structure 308, charge storage layer 313a and the gate structure 320 are connected together in series without gaps to form a memory cell column. And then the source/drain regions 322 and 324 are formed in the substrate 300 next to the memory cell column. The subsequent process for completing the memory array is well known to those skilled in the art, and the unnecessary details are omitted herein.

In the embodiment described above, the gate structure 308, charge storage layer 313a and the gate structure 320 are connected together in series without gaps, so that the integrity of the memory array may be improved. Furthermore, since part of the charge storage layer 313a is located between the gate structure 320 and the substrate 300 respectively, when the non-volatile memory of the present embodiment is erased, the erase efficiency can be raised by the vertical electrical field generated between the gate structure 320 and the substrate 300. The steps of forming the non-volatile memory in the present invention are simply compared with the conventional process, and thus the manufacturing cost may be reduced.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A non-volatile memory, comprising:
a plurality of first gate structures disposed on a substrate;
a plural pairs of charge storage layers, each pair disposed on the sidewalls of the first gate structures, wherein each of the first gate structures and corresponding charge storage layers are disposed from the others by a gap;
a plurality of second gate structures, each disposed in the gap between the first gate structures, wherein the first gate structures, the plural pairs of charge storage layers and the second gate structures constitute a memory column; and
two doped regions, each disposed in the substrate at two sides of the memory column respectively.

2. The non-volatile memory as claimed in claim 1, wherein the material of the charge storage layers comprises silicon nitride or doped polysilicon.

3. The non-volatile memory as claimed in claim 1, wherein the charge storage layers are formed in an “L” shape on the sidewalls of the first gate structures.

4. The non-volatile memory as claimed in claim 3, wherein the material of the charge storage layers comprises silicon nitride or doped polysilicon.

5. The non-volatile memory as claimed in claim 1, wherein the charge storage layers and the gate structures are provided with a first dielectric layer therebetween respectively.

6. The non-volatile memory as claimed in claim 5, wherein the material of the first dielectric layer comprises silicon oxide.

7. The non-volatile memory as claimed in claim 1, wherein the charge storage layers and the substrate are provided with a second dielectric layer respectively.

8. The non-volatile memory as claimed in claim 7, wherein the material of the second dielectric layers comprises silicon oxide.

9. The non-volatile memory as claimed in claim 4, wherein
each of the first gate structures comprises:
a first gate dielectric layer formed on the substrate;
a first gate formed on the first gate dielectric layer; and
a cap layer formed on the first gate; and
each of the second gate structures comprises:
a second gate dielectric layer formed on the substrate; and
a second gate formed on the second gate dielectric layer.

10. The non-volatile memory as claimed in claim 9, wherein the material of the first gate dielectric layer and the second gate dielectric layer comprises silicon oxide.

11. The non-volatile memory as claimed in claim 9, wherein the material of the first gate and second gate comprises doped polysilicon.

12. A method for manufacturing the non-volatile memory, comprising:
providing a substrate;
forming a plurality of first gate structures on the substrate, the two neighboring first gate structures having a gap therebetween;
forming a tunneling dielectric layer on the substrate;
forming a plurality of charge storage layers on the sidewalls of the first gate structures;
forming a plurality of second gate structures on the substrate, wherein the second gate structures fill up the gaps between the first gate structures, and the charge storage layers, second gate structures and the first gate structures constitute a memory cell column; and
forming two doped regions in the substrate next to the memory cell column.

13. The method for manufacturing the non-volatile memory as claimed in claim 12, wherein the steps of forming the first gate structures on the substrate comprise:
forming a first gate dielectric layer on the substrate;
forming a first conductive layer on the first gate dielectric layer;
forming a cap layer on the first conductive layer; and
patterning the cap layer, the first conductive layer and the first gate dielectric layer.

14. The method for manufacturing the non-volatile memory as claimed in claim 13, wherein the material of the first gate dielectric layer comprises silicon oxide.

15. The method for manufacturing the non-volatile memory as claimed in claim 12, wherein the steps of forming a plurality of charge storage layers on the sidewalls of the first gate structures comprise:
forming a first dielectric layer and a charge storage material layer on the substrate; and
removing part of the first dielectric layer and part of the charge storage material layer by anisotropic etching process.

16. The method for manufacturing the non-volatile memory as claimed in claim 15, wherein the material of the charge storage layers comprises silicon nitride.

17. The method for manufacturing the non-volatile memory as claimed in claim 15, further comprising patterning the charge storage layers to form a plurality of charge storage blocks after the step of forming the charge storage layers on the sidewalls of the first gate structures.

18. The method for manufacturing the non-volatile memory as claimed in claim 17, wherein the material of the charge storage blocks comprises silicon nitride or doped polysilicon.

19. The method for manufacturing the non-volatile memory as claimed in claim 12, wherein the steps of forming a plurality of charge storage layers on the sidewalls of the first gate structures comprise:
forming a first dielectric layer on the substrate;
forming a charge storage material layer on the substrate;
forming a sacrificial layer on the substrate;
removing part of the sacrificial layer by anisotropic etching process, so as to form a plurality of spacers on the surface of the charge storage material layer;
removing part of the charge storage material layer and part of the first dielectric layer by using the spacers as masks; and
removing the spacers.

20. The method for manufacturing the non-volatile memory as claimed in claim 19, wherein the charge storage layers are “L” shape.

21. The method for manufacturing the non-volatile memory as claimed in claim 19, wherein the material of the charge storage layers comprises silicon nitride.

22. The method for manufacturing the non-volatile memory as claimed in claim 19, further comprising patterning the charge storage layers to form a plurality of charge storage blocks after the step of forming the charge storage layers on the sidewalls of the first gate structures.

23. The method for manufacturing the non-volatile memory as claimed in claim 22, wherein the material of the charge storage blocks comprises silicon nitride or doped polysilicon.

24. The method for manufacturing the non-volatile memory as claimed in claim 12, wherein the material of the tunneling dielectric layer comprises silicon oxide.

25. The method for manufacturing the non-volatile memory as claimed in claim 12, wherein the steps of forming the second gate structures on the substrate comprise:
forming a second dielectric layer on the substrate;
forming a second conductive layer on the second gate dielectric layer, the second conductive layer filling up the gaps; and
removing part of the second conductive layer until the first gate structures are exposed.

26. The method for manufacturing the non-volatile memory as claimed in claim 12, wherein the method for removing part of the second conductive layer comprises chemical mechanical polishing process.

27. The method for manufacturing the non-volatile memory as claimed in claim 12, wherein the material of the second gate dielectric layer comprises silicon oxide.

28. The method for manufacturing the non-volatile memory as claimed in claim 25, wherein the material of the first conductive layer and second conductive layer comprises doped polysilicon.

29. A method for operating a non-volatile memory array, wherein the memory cell array comprises a plurality of memory cell columns, each of which includes a plurality of gate structures disposed on a substrate and connected in series, a plurality of charge storage layers disposed between the gate structures respectively, wherein every two of the charge storage layers are formed as a pair, and a first source/drain region and a second source/drain region are disposed in the substrate at both sides of the memory cell column respectively; and a plurality of word lines connecting the gate structures in the same row, the method comprising:
during a programming operation, applying a first voltage to a selected word line;
applying a second voltage to other non-selected word lines;
applying a third voltage to the first source/drain region of the selected memory cell column;
applying a fourth voltage to the second source/drain region of the selected memory cell column, wherein the first voltage is higher than or equal to a threshold voltage of the gate structures, the second voltage is higher than the first voltage, and the fourth voltage is higher than the third voltage, so that the charge storage layer adjacent to the selected word line at the second source/drain region side is programmed by source-side injection.

30. The method as claimed in claim 29, wherein the first voltage is about 1.5 V, the second voltage is about 7 V, the third voltage is about 0 V, and the fourth voltage is about 2.5 V.

31. The method as claimed in claim 29, further comprising: during an erase operation, applying a fifth voltage to the word lines, and applying a sixth voltage to the substrate, so as to inject electrons from the charge storage layers to the substrate, wherein a voltage difference between the fifth voltage and the sixth voltage is able to induce FN tunneling effect.

32. The method as claimed in claim 31, wherein the voltage difference is about −12 to −20 V.

33. The method as claimed in claim 31, wherein the fifth voltage is about 0 V and the sixth voltage is about 12 V.

34. The method as claimed in claim 29, further comprising:
during a read operation, applying a seventh voltage to a selected word line;
applying an eighth voltage to the non-selected word lines;
applying a ninth voltage to the first source/drain region of the selected memory cell column;
applying a tenth voltage to the second source/drain region of the selected memory cell column so as to read the charge storage layer adjacent to the selected word line at the second source/drain region side, wherein the ninth voltage is higher than the tenth voltage, the seventh voltage is higher than or equal to the threshold voltage of the gate structures, but lower than the voltage difference between the ninth voltage and the tenth voltage, and the eighth voltage is higher than the seventh voltage.

35. The method as claimed in claim 34, wherein the seventh voltage is about 3.5 V, the eighth voltage is about 7 V, the ninth voltage is about 1.5 V, and the tenth voltage is about 0 V.

36. The method as claimed in claim 29, comprising:
during a read operation, applying an eleventh voltage to a selected word line;
applying a twelfth voltage to other non-selected word lines;
applying a thirteenth voltage to the second source/drain region of the selected memory cell column;
applying a fourteenth voltage to the first source/drain region of the selected memory cell column, so as to read the charge storage layer adjacent to the selected word line at the first source/drain region side, wherein the thirteenth voltage is higher than the fourteenth voltage, the eleventh voltage is higher than or equal to the threshold voltage of the gate structures, but lower than the voltage difference between the thirteenth voltage and the fourteenth voltage, and the twelfth voltage is higher than the eleventh voltage.

37. The method as claimed in claim 36, wherein the eleventh voltage is about 3.5 V; the twelfth voltage is about 7 V; the thirteenth voltage is about 1.5 V; and the fourteenth voltage is about 0 V.

38. A method for operating a non-volatile memory array, wherein the memory cell array comprises:
a plurality of memory cell columns, each of which includes a plurality of first gate structures disposed on a substrate, wherein a gap is disposed between the two neighboring first gate structures, a plurality of second gate structures disposed in the gaps between the first gate structures, a plurality of charge storage layers respectively disposed between the first gate structures and the second gate structures, wherein a bottom portion of each of the charge storage layers is sandwiched between corresponding first gate structure and the substrate, and a first source/drain region and a second source/drain region disposed in the substrate at both sides of the memory cell column respectively; a plurality of word lines connecting the first gate structures in the same row; and a plurality of select gate lines connecting the second gate structures in the same row, the method comprising:
during a programming operation, applying a first voltage to a selected word line;
applying a second voltage to other non-selected word lines and the select gate lines;
applying a third voltage to the first source/drain region of the selected memory cell column;
applying a fourth voltage to the second source/drain region of the selected memory cell column; wherein the first voltage is higher than or equal to the threshold voltage of the first gate structures, the second voltage is higher than the first voltage; the fourth voltage is higher than the third voltage, so that the charge storage layer adjacent to the selected word line at the second source/drain region side is programmed by source-side injection.

39. The method as claimed in claim 38, wherein the first voltage is about 1.5 V, the second voltage is about 9 V, the third voltage is about 0 V, and the fourth voltage is about 3.5 V.

40. The method as claimed in claim 38, further comprising:
during a programming operation, applying a fifth voltage to a selected word line;
applying a sixth voltage to other non-selected word lines and the select gate lines;
applying a seventh voltage to the second source/drain region of the selected memory cell column;
applying an eighth voltage to the first source/drain region of the selected memory cell column; wherein the fifth voltage is higher than or equal to the threshold voltage of the first gate structures, the sixth voltage is higher than the fifth voltage, the eighth voltage is higher than the seventh voltage, so that the charge storage layer adjacent to the selected word line at the first source/drain region side is programmed by source-side injection.

41. The method as claimed in claim 40, wherein the fifth voltage is about 1.5 V, the sixth voltage is about 9 V, the seventh voltage is about 0 V, and the eighth voltage is about 3.5 V.

42. The method as claimed in claim 38, further comprising:
during an erase operation, applying a ninth voltage to the word lines and the select gate lines, and applying a tenth voltage to the substrate so as to inject electrons from the charge storage layers into the substrate, wherein a voltage difference between the ninth voltage and tenth voltage is able to induce FN tunneling effect.

43. The method as claimed in claim 42, wherein the voltage difference is about −12 to −20V.

44. The method as claimed in claim 42, wherein the ninth voltage is about 0 V and the tenth voltage is about 12 V.

45. The method as claimed in claim 38, comprising:
during a read operation, applying an eleventh voltage to a selected word line;
applying a twelfth voltage to other non-selected word lines and the select gate lines;
applying a thirteenth voltage to the first source/drain region of the selected memory cell column;
applying a fourteenth voltage to the second source/drain region of the selected memory cell column so as to read the charge storage layer adjacent to the selected word line at the second source/drain region side, wherein the thirteenth voltage is higher than the fourteenth voltage, the eleventh voltage is higher than or equal to the threshold voltage of the gate structures before the charge storage layer is programmed, but lower than the threshold voltage of the gate structures after the charge storage layer is programmed, and the twelfth voltage is higher than the eleventh voltage.

46. The method as claimed in claim 45, wherein the eleventh voltage is about 2.5 V, the twelfth voltage is about 6 V, the thirteenth voltage is about 1.5 V, and the fourteenth voltage is about 0 V.

47. The method as claimed in claim 38, comprising:
during a read operation, applying a fifteenth voltage to a selected word line;
applying a sixteenth voltage to other non-selected word lines and the select gate lines;
applying a seventeenth voltage to the second source/drain region of the selected memory cell column;
applying an eighteenth voltage to the first source/drain region of the selected memory cell column so as to read the charge storage layer adjacent to the selected word line and at a side of the selected word line adjacent to the second source/drain region, wherein the seventeenth voltage is higher than the eighteenth voltage, the fifteenth voltage is higher than or equal to the threshold voltage of the gate structures before the charge storage layer is programmed, but lower than the threshold voltage of the gate structures after the charge storage layer is programmed, and the sixteenth voltage is higher than the fifteenth voltage.

48. The method as claimed in claim 47, wherein the fifteenth voltage is about 2.5 V, the sixteenth voltage is about 6 V, the seventeenth voltage is about 1.5 V, and the eighteenth voltage is about 0 V.
